(19) United States
(12) Patent Application Publication
(10) Pub. No.: US 2011/0057201 A1
(43) Pub. Date: Mar. 10, 2011

(54) LED Element with a Thin-layer Semiconductor Element Made of Gallium Nitride

(75) Inventor: Stefan Tasch, Jennersdorf (AT)

(73) Assignee: LEDON LIGHTING JENNERSDORF GMBH, Jennersdorf (AT)

(21) Appl. No.: 12/990,441

(22) PCT Filed: Apr. 24, 2009
(86) PCT No.: PCT/EP09/03026

§ 371 Date: Nov. 24, 2010

(30) Foreign Application Priority Data
Apr. 30, 2008 (DE) 10 2008 021 659.3

(51) Int. Cl. H01L 33/30

(52) U.S. Cl. 257/76; 257/E33.025

(57) ABSTRACT

An LED module comprising an LED chip, with an active gallium nitride layer and a silicon platform on which the LED chip is arranged, wherein the silicon platform has two electrodes on the side facing away from the LED chip which are electrically connected to the LED chip and wherein the thickness of the gallium nitride layer of the LED chip is between 2 μm and 10 μm, preferably 1 μm to 5 μm.

The present invention relates to an LED element, having a thin-film semiconductor component (“chip”) based on gallium nitride, which is arranged on a silicon platform which has, on a side facing away from the semiconductor component, electrodes which are connected electrically to the semiconductor component.

### BACKGROUND OF THE INVENTION

Conventional radiation-emitting semiconductor components generally comprise a carrier substrate and a multilayer structure which is grown epitaxially on said carrier substrate and has an active radiation-producing layer. In this case, the carrier substrate is preferably electrically conductive in order to enable a vertical current flow through the semiconductor component. In many application cases, it is also desirable for the carrier substrate to be transparent to the radiation emitted by the active layer. However, it should be noted that the transparency of the substrate layer with respect to the emitted radiation of the active layer of the semiconductor component is often inconsistent with the desired electrical conductivity of the carrier substrate. For light-emitting diodes based on gallium nitride, for example, sapphire (Al₂O₃) can be used as the material for the carrier substrate, which is transparent to blue light, but does not electrically conduct it. For this reason, silicon carbide (SiC) is often used as the carrier substrate for light-emitting diodes based on gallium nitride since it has both high transparency and high electrical conductivity. However, characteristic of the material silicon carbide as the carrier substrate is the fact that its transparency decreases as the conductivity increases.

In order to improve the effectiveness of light-emitting diodes further, so-called thin-film semiconductor components have been developed. These are semiconductor components in which the substrate layer is used for the crystal growth but is removed after this process. The resultant thin film enables more effective light emission than using conventional technologies since no substrate layer is provided which absorbs some of the light emission. This also results in improved heat dissipation.

In order to remove the substrate layer, a chemical or physical process is generally used. For example, by means of the so-called laser lift-off method, the light from a pulsed UV laser can be used for removing the substrate layer without the gallium nitride layer, which is 5 μm thick, for example, being destroyed in the process.

US20060240585A1 has disclosed a layered structure (p, n and active layers) with a thickness of 3 μm. As regards the structure of a radiation-emitting component based on GaN, i.e. with an epitaxially grown stack of GaN layers, express reference is made to this specification in order to avoid any repetition.

Radiation-emitting components based on GaN are known, for example, from U.S. Pat. No. 5,874,747.

WO 2006/065046 describes a method for producing a thin-film semiconductor component based on gallium nitride. In this case, a so-called laser lift-off method is used for removing the sapphire substrate layer on which the crystal structure of the LED is grown. Prior to the removal of the substrate layer, the crystal structure is applied to an additional substrate layer. Then, in a further method step, splitting is performed into uniform LED chips.

DE10056475 has disclosed a radiation-emitting semiconductor component based on GaN with a semiconductor body, which has an SiC-based substrate, to which a plurality of GaN-based layers is applied, this plurality containing at least one active region, which is arranged between at least one n-conducting layer and at least one p-conducting layer, characterized by the fact that the p-conducting layer is grown with tensile compression.

Haerle et. al. “High brightness LEDs for general lighting applications Using the new ThinGaN™-Technology”, physica status solidi (a), Volume 201, Issue 12 , Pages 2736-2739, has disclosed, in principle, the use of thin GaN technology in the field of powerful LEDs.

Building on this prior art, the present invention is based on the object of providing an LED element which has a thin-film semiconductor component based on gallium nitride, the LED module having improved thermal properties and a more compact design in comparison with the prior art.

Semiconductor components (“chips”) based on gallium nitride are preferably used for producing radiation in the blue-green spectral range. In addition to gallium nitride (GaN), in the context of the present invention a GaN-based material is understood to mean all GaN-related or derived mixed crystals. These include in particular the materials gallium nitride (GaN), indium nitride (InN) aluminum nitride (AlN).

### OBJECT AND SUMMARY OF THE INVENTION

The invention relates to an LED module having at least one LED chip, having an active gallium nitride layer, and a silicon platform on which the LED chip is arranged, the silicon platform having, on one side facing away from the LED chip, two electrodes which are electrically connected to the LED chip, and the total thickness of the epitaxial gallium nitride layers (n-type and p-type, active GaN layer) of the LED chip which lie one above the other being between 2 and 10 μm, preferably being from 2 to 5 μm.

The silicon platform has a cavity in which the LED chip is arranged (alternatively a frame surrounding the LED chip can be provided separately or in integrated fashion on the silicon platform). In this case, the LED chip is preferably arranged centrally in the cavity. In addition, the LED chip is arranged at a predefined distance from the edge of the cavity. The cavity is preferably square or circular. However, it can also have a different shape. The cavity can also be elliptical or triangular, for example.

The GaN layers according to the invention have GaN-derived or GaN-related materials and ternary or quaternary mixed crystals constructed thereon. Examples are AlN, InN, AlGaN (Al1-xGaxN, 0</=x</=1), InGaN (In1-xGaxN, 0</=x</=1), InAlN (In1-xAlxN, 0</=x</=1) and AlInGaN (Al1-x-yInxGayN, 0</=x</=1, 0</=y</=1).

The generation of the thin-film semiconductor component which has a gallium nitride layer is in this case preferably performed by a laser lift-off method or another method which is suitable for separating the gallium nitride layer from the substrate layer. The gallium nitride layer is preferably grown on a sapphire carbide or silicon carbide substrate layer and, by virtue of the above-described method, is free from substrate.

The LED chip according to the invention is preferably applied to the silicon platform by means of bonding wires or by means of flip-chip technology. The LED chip can therefore be arranged on the silicon platform in the “face-up” or “face-down” position.

The electrodes are preferably arranged on the lower side of the silicon platform. This makes it possible for the LED module to be linked electrically to a current source or controller in a more simple manner.

The silicon platform of the LED module according to the invention preferably has vias, which electrically connect the electrodes on the lower side of the silicon platform to electrodes of the LED chip. The vias in this case preferably extend from a first side of the silicon platform to a second side of the platform. The cross-sectional shape of the bores is preferably radial and has a diameter of 0.1-0.5 mm. In addition, the bores are preferably filled with electrically conductive material, for example copper, gold. Explicit reference is made to the fact that the vias can also have a different cross-sectional shape, for example a square shape. The generation of the vias in the silicon platform can be performed by dry or wet etching, for example.

The epitaxial LED GaN layers (n, p and active layers) are preferably arranged directly on the surface of the silicon platform. This means that there are no further interlayers (or substrate) between the gallium nitride layer of the LED chip and the silicon platform. The surface of the silicon platform is in this case preferably larger than that surface of the LED chip which is in contact with the silicon platform.

Furthermore, the silicon platform preferably extends laterally beyond the LED chip. Owing to this arrangement, in particular the thermal properties of the LED module are markedly improved. Improved heat dissipation away from the LED chip is therefore possible. In addition, the physical size of the LED chip can be reduced.

The LED chip is electrically connected to the vias of the silicon platform, preferably by means of flat contacts or so-called “bumps”. The flat contacts in this case have the advantage of improved heat dissipation. However, it is also possible to electrically connect the GaN chip and the silicon plate (silicon platform) with the aid of bonding wires.

The cavity can be filled at least partially with a color conversion layer. The color conversion layer in this case preferably comprises a liquid, curable and optically transparent material, which contains phosphor particles as the phosphor. A BOSE or YAG phosphor can be used as the phosphor, for example. The color conversion layer covers the LED chip arranged in the cavity, preferably without any gas inclusions.

The volume of the cavity can be filled with a color conversion layer so as to be flush with the surface of the silicon platform. In this case, the initially liquid color conversion layer is preferably introduced into the cavity with the aid of a dispensing operation. In this way, it is naturally also possible for a scattering layer to be introduced into the cavity. The layers applied by means of such a procedure can be cured successively or simultaneously. In this case, successive curing of the layers means that first a first layer is dispensed, and this is then heat-treated in a subsequent curing operation, before a further layer is applied onto this first layer by means of a dispensing operation. Simultaneous curing means that the individual color conversion layers and/or scattering layers are first applied on top of one another at different times and then jointly heat-treated in a single curing operation.

Preformed color conversion elements with phosphor and/or scattering particles can also be applied.

It is also possible to arrange a light disk or lens above the LED chip. In this case, color conversion medium can be dispersed in this light disk.

The LED module according to the invention has more compact dimensions in comparison with the conventional LED modules. Further advantages are increased efficiency and improved heat dissipation (“thermal management”).

Specifically, the silicon platform preferably has a thickness which is less than 500 μm. The thickness of the silicon platform beneath a cavity formed therein is preferably less than 300 μm.

The dimensions of the length and width of the silicon platform are preferably between 1.0 and 6.5 mm. In this case, a length or width of the silicon platform of between 1 and 2.5 mm is particularly preferred.

In a further preferred embodiment, the LED chip is arranged on an additional silicon substrate layer, the silicon substrate layer and the LED chip arranged thereon having identical dimensions with respect to their length and width. When viewed from above, the contour of the LED chip therefore covers the silicon substrate layer. Preferably, the length and width of the silicon substrate layer in this case have a value of between 1 and 3 mm.

The LED chips according to the invention with Si and GaN can be assembled easily and the wafers thus produced can be separated from one another in the same way as known LED chips.

### DETAILED DESCRIPTION OF THE DRAWINGS

A preferred exemplary embodiment of the LED module according to the invention is illustrated in the drawings and will be explained in more detail in the description below.

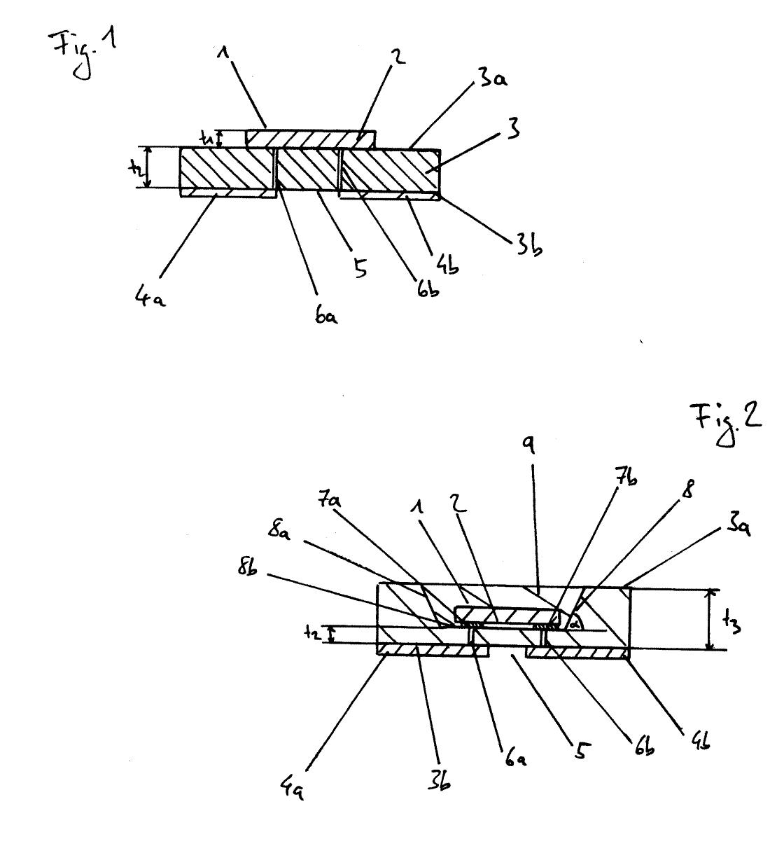

FIG. 1 shows a lateral sectional view of a preferred exemplary embodiment of the LED module according to the invention, with the gallium nitride layer of the LED chip being arranged directly on the silicon platform.

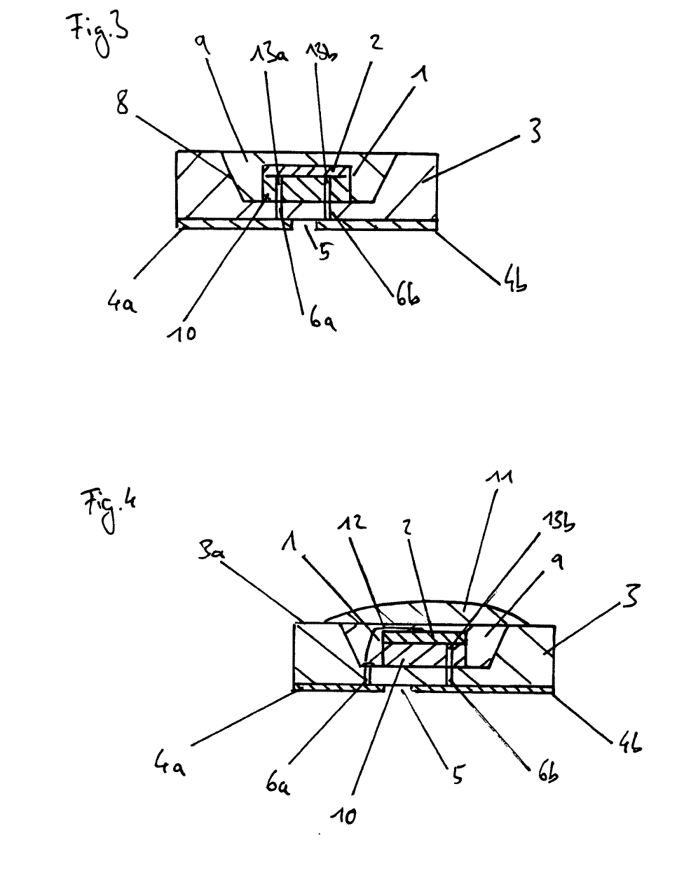

FIG. 2 shows a further preferred exemplary embodiment of the LED module according to the invention, with the silicon platform having a cavity in which the LED chip is arranged.

FIG. 3 shows a further preferred exemplary embodiment of the LED module according to the invention, with the gallium nitride layer of the LED chip being applied to an additional silicon substrate, which is arranged on the surface of the silicon platform.

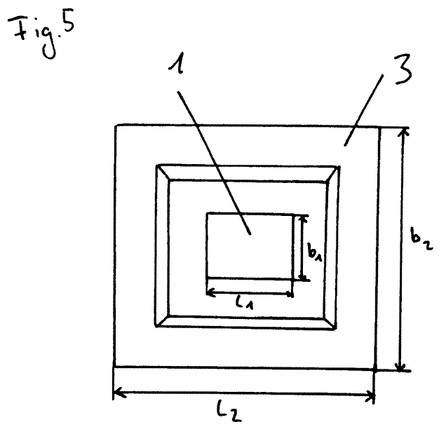

FIG. 4 shows a further preferred exemplary embodiment of the LED module according to the invention as shown in FIG. 3, with two color conversion layers being applied above the LED chip.

FIG. 5 shows a preferred exemplary embodiment of an LED module according to the invention in a plan view.

### DETAILED DESCRIPTION OF THE EMBODIMENTS

FIG. 1 shows a lateral sectional view of a preferred exemplary embodiment of the LED module according to the invention. The LED chip 1 is a chip which has substantially a plurality of epitaxial gallium nitride layers 2 and is arranged on a platform 3.

“Gallium nitride layer” is understood to mean a layer based on GaN or based on a GaN-related or GaN-derived mixed crystal, i.e. for example also indium nitride (InN) and aluminum nitride (AlN).

Preferably, these epitaxial gallium nitride layers 2 represent all epitaxial layers of the LED chip.

According to the invention, the platform consists of silicon. It is of course also possible for a plurality of LED chips 1 to be arranged on the silicon platform 3.

The thickness t₂ of the silicon platform 3 is between 100 and 500 μm according to the invention. The total thickness t₁ of the gallium nitride layers 2 (and therefore the total thickness of all of the epitaxial layers) of the at least one LED chip 1 is between 1 and 10 μm, preferably between 1 and 5 μm according to the invention.

The silicon platform 3 has an upper side 3a and a lower side 3b. The LED chip 1 is preferably arranged on the upper side 3a. Two electrodes 4a, 4b are located on the lower side 3b of the silicon platform 3 and therefore on a side facing away from the LED chip. The electrodes 4a, 4b are preferably flat contacts. An air gap between the electrodes represents the electrical insulation. The size of the electrodes is, for example, 200 □m by 200 □m.

The silicon platform 3 preferably has vias 6a, 6b, which electrically connect the electrodes 4a, 4b to the LED chip 1. The vias 6a, 6b or flat contacts (4a, 4b) are applied to an electrically insulated (with an oxide or nitride layer) Si platelet.

FIG. 2 shows a further preferred exemplary embodiment of the present invention. In this exemplary embodiment, the silicon platform 3 has a cavity 8, in which the LED chip 1 is arranged. The LED chip is in this case preferably arranged centrally in the cavity 8. In this exemplary embodiment, the silicon platform 3 has a thickness t₃ of between 400 and 700 μm. The thickness t₂ of the silicon platform 3 beneath the LED chip 1 is between 50 and 300 μm according to the invention.

The cavity 8 has a flat base area 8b, which extends parallel to the surface 3a of the silicon platform 3. A side face 8a of the cavity 8 connects the base area 8b to the surface 3a of the silicon platform 3. The cavity 8 is preferably circular or rectangular. The side face 8a can be inclined at any desired angle α of between 1 and 90° with respect to the surface 3a of the silicon plafform. Preferably, the value of the angle α is between 45 and 90°. The side face 8a and the base area 8b preferably have a reflective surface. This can produce regular or diffuse reflection. Correspondingly, the luminous efficacy of the LED module can be increased.

As is illustrated in FIG. 2, the LED chip 1 is connected electrically to the electrodes 4a, 4b with the aid of contact faces or contact layers 7a, 7b and vias 6a, 6b. The contact layers 7a, 7b are preferably made from gold tin (AuSn), which has a thermal conductivity of 57 W/m-K. As a result, optimum heat dissipation away from the LED chip 1 towards the silicon platform 3 can be achieved. It is also possible to use so-called bumps as the contact faces.

The cavity 8 of the LED module is filled with at least one color conversion layer 9, which covers the LED chip 1 without a gas inclusion. Phosphor particles are preferably dispersed in the color conversion layer 9 in order to enable color conversion of the radiation emitted by the LED chip 1. As illustrated in FIG. 2, the color conversion layer 9 is preferably designed to be flush with the surface 3a of the silicon platform. However, it is also possible for the color conversion layer 9 to only partially fill the volume of the cavity 8. The surface of the color conversion layer 9 can be flat, concave or convex.

A layer with scattering particles can be arranged on the color conversion layer 9. This layer can be dispensed or applied as a molding.

FIG. 3 shows a lateral sectional view of a further preferred embodiment of the LED module according to the invention. In this embodiment, the active gallium nitride layer, which only represents one of the plurality of GaN layers 2, is arranged on an additional substrate layer 10, which preferably consists of silicon. This substrate layer 10 is accordingly located between the gallium nitride layers 2 and the silicon platform 3. This has the advantage in terms of production technology that the assembled Si and GaN layers can be separated easily and can be handled as wafers.

The silicon substrate layer 10 is in this case arranged on the surface 3a of the silicon platform 3. The silicon substrate layer 10 preferably has vias 13a, 13b, which electrically connect the active gallium nitride layer 2 to the vias 6a, 6b of the silicon platform 3. The vias 13a, 13b of the silicon substrate layer 10 preferably have the same cross section as the vias 6a, 6b. The silicon substrate layer 10 preferably has a thickness of 50-100 μm.

The silicon substrate layer 10 preferably has the same dimensions as the gallium nitride layers 2 with respect to their length l₁and width b₁ (see FIG. 5). This means that the contours of the gallium nitride layers 2 preferably cover the silicon substrate layer 10 when viewed from above. However, it should be mentioned that the dimensions of the length l₁ and width b₁ of the silicon substrate layer 10 and the gallium nitride layers 2 can deviate from one another by up to 10%. This means that the surface of the silicon substrate layer 10 on which the gallium nitride layers 2 are applied can be up to 10% larger.

The substrate layer 10 is preferably applied to the gallium nitride layer 2 before removal of the initial substrate layer, which consists of silicon carbide or sapphire, and on which the epitaxial gallium nitride layers 2 are grown epitaxially.

It should be mentioned that the number of vias 6a, 6b, 13a, 13b is not restricted to a specific quantity. Instead, a large number of vias 6a, 6b, 13a, 13b can be arranged in the substrate layer 10 and the silicon platform 3 in order to produce an electrical connection between the electrodes 4a, 4b and the LED chip 1.

FIG. 4 illustrates a further preferred exemplary embodiment of the LED module according to the invention. As already described with reference to FIG. 3, the epitaxial LED layers based on GaN are arranged on a silicon substrate layer 10. In this exemplary embodiment, the LED module has at least one bonding wire 12, which connects the LED chip 1 to at least one via 6a of the silicon platform 3. In this exemplary embodiment, the silicon substrate 10 has one or more vias 13b, which are connected electrically to only one electrode 4b of the LED module.

As can be seen from FIG. 4, the size of the two electrodes 4a, 4b can deviate from one another. This can be advantageous for the heat dissipation away from the LED chip 1.

As illustrated in FIG. 4, a color conversion layer and a scattering layer 9, 11 are arranged on the LED chip 1. In this case, the first layer 9 is preferably shaped so as to be parallel to the surface 3a of the silicon platform 3. The scattering layer 11 is applied above the first layer 9 with the aid of a so-called dispensing method. The surface of the scattering layer 11 is preferably convex. The diameter of the second color conversion layer 11 is preferably greater than the diameter of the cavity 8. In this way, all of the radiation emitted by the surface of the first color conversion layer 9 is transmitted through the scattering layer 11. The scattering layer can also have scattering particles in a low concentration.

The concentration of color conversion medium within the color conversion and scattering layers 9, 11 can deviate from one another.

FIG. 5 shows a plan view of an LED module according to the invention. In this case, the length l₁ and the width b₁ of the LED chip 1 typically have a value of between 0.5 and 1.5 mm. The length l₁ and the width b₁ of the silicon platform is between 1.0 and 6.5 mm. Preferably, the silicon platform has a value of between 1 and 2.5 mm.

1. A light-emitting diode (LED) module, having an LED chip with a plurality of epitaxial gallium nitride layers positioned directly one above the other and a silicon platform, on which the LED chip is arranged, the gallium nitride layers having at least one n-doped layer, an active layer, and a p-doped layer, the silicon platform having, on one side facing away from the LED chip, two electrodes, which are electrically connected to the LED chip, the total thickness of the epitaxial gallium nitride layers of the LED chip being between 1 μm and 10 μm, and the silicon platform having a cavity, in which the LED chip is arranged.

2. The LED module as claimed in claim 1, the silicon platform having vias, which electrically connect the electrodes of the silicon platform to the LED chip.

3. The LED module as claimed in claim 1, the epitaxial gallium nitride layers being arranged directly, without any interlayers, on a surface of the silicon platform.

4. The LED module as claimed in claim 2, the LED chip being electrically connected to the vias of the silicon platform by bumps or flat contacts (7a, 7b).

5. The LED module as claimed in claim 1, the cavity of the silicon platform being filled with a color conversion layer and/or a layer with scattering particles.

6. The LED module as claimed in claim 1, the thickness (t₂) of the silicon platform beneath the LED chip being less than 300 μm.

7. The LED module as claimed in claim 1, comprising an additional silicon substrate layer located between the gallium nitride layers and the silicon platform.

8. The LED module as claimed in claim 7, the gallium nitride layers and the silicon substrate layer having identical dimensions in terms of their respective width and length.

9. The LED module as claimed in claim 1, a length and width of the silicon platform each being between 2.5 mm and 6.5 mm.

10. The LED module as claimed in claim 1, the LED chip being arranged in the face-up or face-down position on the silicon plafform.

11. The LED module as claimed in claim 1 wherein the total thickness of the epitaxial gallium nitride layers of the LED chip is between 2 μm and 5 μm.
